(19) United States
(12) Patent Application Publication
(10) Pub. No.: US 2019/0242011 A1
(43) Pub. Date: Aug. 8, 2019

(54) PROCESSING SYSTEM, METHOD FOR PROCESSING A FLEXIBLE SUBSTRATE, AND DEPOSITION APPARATUS

(71) Applicants: Reiner GERTMANN, Linsengericht (DE); Hans-Georg LOTZ, Gründau-Rothenbergen (DE); Applied Materials, Inc., Santa Clara, CA (US)

(72) Inventors: Reiner GERTMANN, Linsengericht (DE); Hans-Georg LOTZ, Gründau-Rothenbergen (DE)

(21) Appl. No.: 16/312,122

(22) PCT Filed: Jul. 1, 2016
(86) PCT No.: PCT/EP2016/065554

§ 371 Date: Dec. 20, 2018

(51) Int. Cl. C23C 14/54; C23C 14/56

(52) U.S. Cl. CPC C23C 14/547; C23C 14/562

(57) ABSTRACT

According to one aspect of the present disclosure, a processing system for processing a flexible substrate is provided. The processing system includes: a vacuum chamber; a transport system configured to guide the flexible substrate through the vacuum chamber along a substrate transportation path (P), wherein the transport system comprises a first substrate support and a second substrate support arranged at a distance from the first substrate support; and an inspection system for inspecting the flexible substrate. The inspection system includes: a light source configured to direct a light beam through a portion of the flexible substrate between the first substrate support and the second substrate support; and a light detector for detecting the light beam for conducting a transmission measurement of the flexible substrate, wherein at least one of the light source and the light detector is arranged in an environment configured for a second pressure level different from a first pressure level in the vacuum chamber. According to a further aspect, a deposition apparatus is provided. According to a further aspect, a method processing a flexible substrate is provided.

### TECHNICAL FIELD

Embodiments of the present disclosure relate to a processing system for processing a flexible substrate, wherein the processing system includes an inspection system for inspecting the flexible substrate. Embodiments of the present disclosure further relate to a deposition apparatus for coating a flexible substrate and for inspecting one or more coating layers deposited on the flexible substrate. Embodiments also relate to methods of processing of a flexible substrate in a vacuum chamber, wherein an optical quality of the processed substrate is inspected by conducting a transmission measurement of the processed substrate.

### BACKGROUND

Substrates, e.g. flexible substrates, are regularly processed while being moved past processing equipment. Processing may comprise coating of a flexible substrate with a coating material, e.g. metal, particularly aluminum or copper, semiconductors or dielectric materials. Particularly, coating of metal, semiconductor or plastic films or foils is in high demand in the packaging industry, semiconductor industry and other industries. Systems performing this task generally include a coating drum coupled to a transport system for moving the substrate along a substrate transportation path, wherein at least a portion of the substrate is processed while the substrate is guided on the coating drum. So-called roll-to-roll (R2R-) coating systems allowing substrates to be coated while being moved on the guiding surface of a coating drum can provide a high throughput.

An evaporation process, such as a thermal evaporation process, a PVD (physical vapor deposition) process and/or a CVD (chemical vapor deposition) process can be utilized for depositing thin layers of coating material on the flexible substrate. Roll-to-roll deposition systems are also experiencing a strong increase in demand in the display industry and the photovoltaic (PV) industry. For example, touch panel elements, flexible displays, and flexible PV modules result in an increasing demand for depositing suitable layers in roll-to-roll coaters with low manufacturing costs. Such devices are typically manufactured with several layers of coating material, which may be produced in roll-to-roll coating apparatuses which successively utilize several deposition units. The deposition units may be adapted for coating the substrate with a particular coating material while the substrate is moved past the deposition units by a transport system, e.g. a roller assembly.

In some applications, substrates, e.g. flexible substrates such as foils or inflexible substrates such as glass plates, are inspected to monitor the quality of the substrates. For example, substrates on which layers of coating material are deposited are manufactured for the display market. Since defects may occur during the coating of the substrates, an inspection of the substrates for reviewing the defects and for monitoring the quality of the substrates is reasonable.

There remains a need for inspection systems for conducting transmission measurements of a flexible substrate with an improved inspection quality. Further, providing a maintenance-friendly inspection system adapted for being used in a vacuum processing system is beneficial.

### SUMMARY

In light of the above, a processing system for processing a flexible substrate as well as a deposition apparatus for coating a flexible substrate are provided. Further, methods of processing a flexible substrate are provided. Further aspects, benefits, and features of the present disclosure are apparent from the claims, the description, and the accompanying drawings.

According to one aspect of the present disclosure, a processing system for processing a flexible substrate is provided. The processing system includes: a vacuum chamber; a transport system configured to guide the flexible substrate through the vacuum chamber along a substrate transportation path, wherein the transport system comprises a first substrate support and a second substrate support arranged at a distance from the first substrate support; and an inspection system for inspecting the flexible substrate. The inspection system includes: a light source configured to direct a light beam through a portion of the flexible substrate between the first substrate support and the second substrate support; and a light detector for detecting the light beam for conducting a transmission measurement of the flexible substrate, wherein at least one of the light source and the light detector is arranged in an environment configured for a second pressure level different from the first pressure level in the vacuum chamber.

According to a further aspect of the present disclosure, a deposition apparatus for coating a flexible substrate is provided. The deposition apparatus includes: a vacuum chamber comprising a coating drum configured for guiding the flexible substrate past one or more deposition units and a wind-up spool for winding the flexible substrate thereon; a roller assembly configured to guide the flexible substrate along a substrate transportation path from the coating drum to the wind-up spool, wherein the roller assembly comprises a first roller and a second roller arranged at a distance from the first roller; and an inspection system for inspecting the flexible substrate, wherein the inspection system includes: a light source configured to direct a light beam through a portion of the flexible substrate between the first roller and the second roller; and a light detector for detecting the light beam for conducting a transmission measurement of the flexible substrate, wherein at least one of the light source and the light detector is arranged in an environment configured for a second pressure level different from a first pressure level in the vacuum chamber.

According to a further aspect of the present disclosure, a method of processing a flexible substrate is provided. The method includes: guiding the flexible substrate through a vacuum chamber along a substrate transportation path, wherein the vacuum chamber is evacuated to a first pressure level and wherein the flexible substrate is supported by a first substrate support and by a second substrate support arranged at a distance from the first substrate support; directing a light beam through a portion of the flexible substrate between the first substrate support and the second substrate support; and detecting the light beam having passed through the flexible substrate for conducting a transmission measurement of the flexible substrate, wherein at least a portion of the light beam propagates through an environment with a second pressure level different from the first pressure level.

Further aspects, advantages, and features of the present disclosure are apparent from the dependent claims, the description, and the accompanying drawings.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following. Typical embodiments are depicted in the drawings and are detailed in the description which follows.

FIG. 1 shows a schematic side view of a processing system according to embodiments described herein;

FIG. 2 shows a schematic side view of a processing system according to embodiments described herein;

FIG. 3 shows a schematic sectional view of a processing system according to embodiments described herein;

FIG. 4 shows a perspective top view of a processing system according to embodiments described herein;

FIG. 5 shows a schematic side view of a deposition apparatus according to embodiments described herein; and

FIG. 6 is a flow diagram of a method of processing a flexible substrate according to embodiments described herein.

### DETAILED DESCRIPTION

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment applies to a corresponding part or aspect in another embodiment as well.

According to embodiments described herein, a processing system for processing a flexible substrate is provided. The processing system may be configured to coat the flexible substrate with one or more layers, e.g. metal layers, dielectric layers, and/or semiconductor layers.

The term substrate as used herein shall particularly embrace flexible substrates such as a plastic film, a web, a foil, or a strip. The term substrate shall also embrace other types of flexible substrates. It is noted that a flexible substrate as used within the embodiments described herein is typically bendable. The term “flexible substrate” or “substrate” may be synonymously used with the term “foil” or the term “web”. In particular, it is to be understood that some embodiments of the processing system described herein can be utilized for coating any kind of flexible substrate, e.g. for manufacturing flat coatings with a uniform thickness, or for manufacturing coating patterns or coating structures in a predetermined shape on the flexible substrate or on top of an underlying coating structure. For example, electronic devices may be formed on the flexible substrate by masking, etching and/or depositing. For example, a flexible substrate as described herein may include materials like PET, HC-PET, PE, PI, PU, TaC, OPP, CPP, one or more metals, paper, combinations thereof, and coated substrates like Hard Coated PET (e.g. HC-PET, HC-TaC) and the like. In some embodiments, the flexible substrate is a COP substrate provided with an index matched (IM) layer on both sides thereof.

A flexible substrate may be moved while being processed in a vacuum chamber. For example, the flexible substrate may be transported along a substrate transportation path P past deposition units for coating the flexible substrate. In some implementations, the substrate may be unwound from a storage roller, may be transported on the outer surface of a coating drum, and may be guided along the outer surfaces of further rollers. The coated flexible substrate may be wound onto a wind-up spool.

According to some embodiments, which can be combined with other embodiments described herein, the processing system may be configured for processing a substrate with a length of 500 m or more, 1000 m or more, or several kilometres. The substrate width can be 100 mm or more, 300 mm or more 500 mm or more, or 1 m or more. The substrate width can be 5 m or less, particularly 2 m or less. Typically, the substrate thickness can be 20 μm or more and 1 mm or less, particularly from 50 μm to 200 μm.

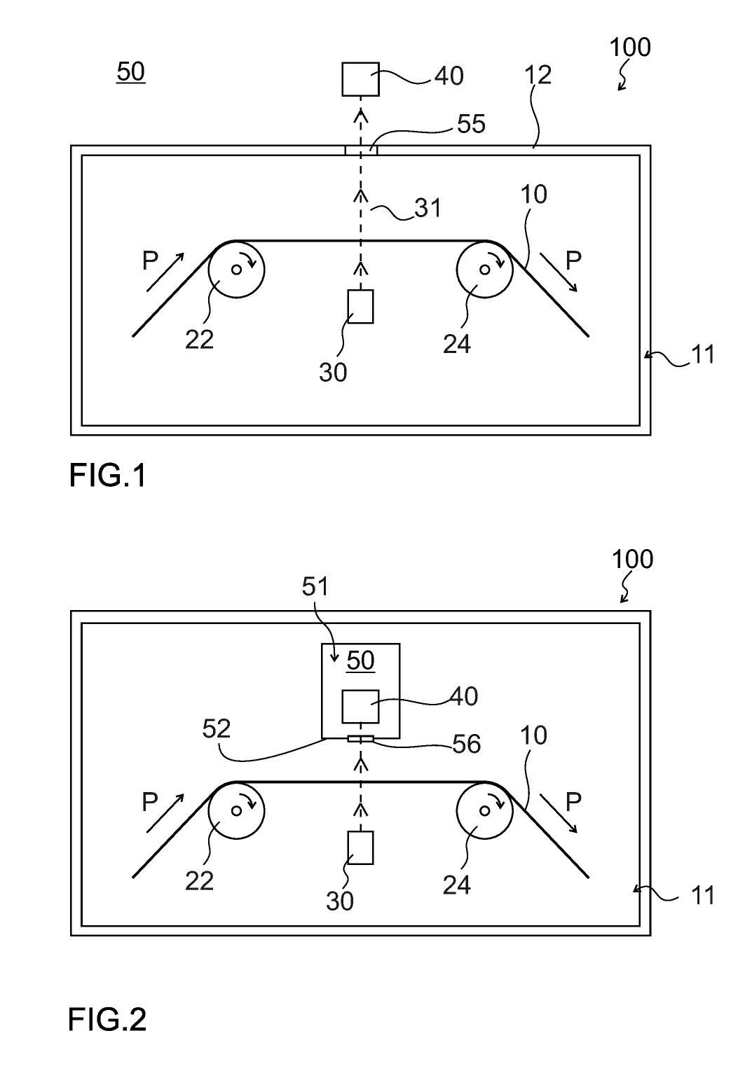

FIG. 1 shows a schematic side view of a processing system 100 according to embodiments described herein. The processing system includes a vacuum chamber 11 and a transport system configured to guide the flexible substrate through the vacuum chamber 11 along a substrate transportation path P, wherein the transport system includes a first substrate support 22 and a second substrate support 24 arranged at a distance from the first substrate support 22. An inspection system is provided for inspecting the flexible substrate 10, particularly for inspecting the coated flexible substrate having one or more coating layers deposited thereon. Specifically, “inspecting the flexible substrate” may be understood as inspecting the flexible substrate before or after deposition, and particularly inspecting one or more coating layers deposited on the flexible substrate.

For example, a property of one or more coating layers deposited on the flexible substrate may be inspected. Coated substrates such as flexible plastic films with one or more layers deposited thereon can be characterized by specified spectral reflectance and transmittance values. Properties of the coated substrates, particularly optical properties such as reflectivity and transmittivity, can be measured with optical inspection systems. Inspection systems may be used to detect and identify defects in or on a substrate, e.g. micro-particles such as μm-sized particles on a processed substrate or defects such as openings, pinholes or cracks in one or more coating layers deposited on the substrate. Inspection systems may be used to inspect a stationary or a moving substrate, wherein defects can be examined with an improved resolution as compared to human eye inspection.

For example, processing systems described herein may be used for the deposition of barrier layers on flexible substrates, e.g. on plastic films. The coated substrates may be further processed together with additional film materials to compound films for food packaging. Coating the flexible substrate with one or more barrier layers may reduce the permeation rates for gases such as oxygen, carbon dioxide and water vapor. Thus, the shelf life of products packed into the compound films can be increased, and the quality of the packed food can be maintained over a longer period of time. The barrier properties of compound films may depend on the type and thickness of the flexible substrate as well as on the type and thickness of the barrier layer(s) deposited thereon. Coating materials for plastic substrates which provide vapor barrier properties are aluminum and aluminum oxide.

The structure and morphology of the compound films may depend on the cleanliness of the surface of the flexible surface before depositing the barrier layer. Debris and small particles may be present on the surface of the flexible substrate before coating. These particles may be overcoated with the barrier layer and may be later mechanically removed by rollers of the transport system configured for transporting the flexible substrate. The resulting defects are called pin-windows or pinholes. At the positions of these defects, the compound films may not include the barrier layer, resulting in a reduced gas barrier. Also other kinds of defects may be present on the coated substrate, such as cracks, reducing the total barrier properties of the food packaging film. Defects in the coated film can be detected by an inspection system which may be used for quality inspection of the coated substrate.

As is shown in FIG. 1, the flexible substrate 10 may be carried and conveyed from the first substrate support 22 to the second substrate support 24 along the substrate transportation path P. The inspection system may be provided at a position between the first substrate support 22 and the second substrate support 24. The area between the first substrate support 22 and the second substrate support 24, where the flexible substrate 10 is not supported on a substrate support surface, may also be referred to as “free span” or “free span position”.

According to some embodiments described herein, the inspection system may include a light source 30 configured to direct a light beam 31 through an unsupported portion of the flexible substrate 10 between the first substrate support 22 and the second substrate support 24, and a light detector 40 for detecting the light beam 31 for conducting a transmission measurement of the flexible substrate 10. In other words, the light source 30 may be configured to direct the light beam 31 through a gap between the first substrate support 22 and the second substrate support 24 such that the light beam may hit the flexible substrate at a portion of the substrate which is not in direct contact with the support surface, i.e. at an unsupported portion of the substrate. Accordingly, a “free span portion” of the flexible substrate may be inspected. A transmission measurement of the substrate can be conducted, because the light beam being transmitted through the flexible substrate is not blocked or impaired by the first substrate support or by the second substrate support, as the light beam may propagate through a gap therebetween.

According to embodiments described herein, the light source 30 may be configured to direct the light beam 31 toward the light detector 40. The light detector may detect the light beam having propagated through the flexible substrate. In some embodiments, the light source 30 may be arranged on a first side of the substrate transportation path, and the light detector 40 may be arranged on a second side of the substrate transportation path, wherein the second side is the opposite side of the substrate transportation path. Thus, during operation of the processing system, the light source may be arranged on a first side of the flexible substrate, and the light detector may be arranged on the opposite side of the flexible substrate such that the light may be directed from the light source to the light detector through the flexible substrate which may be located between the light source and the light beam. In other embodiments, both the light source and the light detector may be arranged on the same side of the substrate transportation path, and the light beam having propagated through the flexible substrate may be redirected toward the light detector by a reflection element, e.g. a retroreflector, or a deflection element, e.g. a mirror.

In some embodiments, at least one of the light source 30 and the light detector 40 is arranged in an environment 50 configured for a second pressure level different from the first pressure level in the vacuum chamber 11. For example, the light source and/or the light detector may be provided under atmospheric pressure, when the vacuum chamber is evacuated to the first pressure level below atmospheric pressure.

The first pressure level, i.e. the pressure level in the vacuum chamber, may be a pressure below atmospheric pressure. For instance, the processing system may include components and equipment allowing for generating or maintaining a vacuum in a main volume of the vacuum chamber. The processing system may include vacuum pumps, evacuation ducts, vacuum seals and the like for generating or maintaining the vacuum in the vacuum chamber. For instance, the vacuum chamber may have one or more vacuum pumps for evacuating the vacuum chamber. In some embodiments, two or more turbo-vacuum pumps may be connected to the vacuum chamber.

Accordingly, the vacuum chamber may form a vacuum tight enclosure, i.e. can be evacuated to a vacuum with the pressure of 10 mbar or less, particularly 1 mbar or less, or even to a pressure between 1×10⁻⁴ and 1×10⁻² mbar or less during deposition. Different pressure ranges are to be considered specifically for PVD processes such as sputtering, which may be conducted in the 10⁻³-mbar range, and CVD processes, which are typically conducted in the mbar-range. Further, the vacuum chambers can be evacuated to a background vacuum with a pressure of 1×10⁻⁶ mbar or less. Background pressure means the pressure which is reached by evacuation of a chamber without any inlet of any gases.

According to embodiments described herein, the light source and/or the light detector may not be arranged in the main volume of the vacuum chamber that is evacuated to the first pressure level during operation, but in an environment which may be pressure-separated from the main volume of the vacuum chamber. For example, the light source and/or the light detector may be arranged outside the vacuum chamber, e.g. outside the walls of the vacuum chamber, i.e. under atmospheric pressure. Alternatively, the light source and/or the light detector may be arranged in a vacuum-tight enclosure, e.g. a vacuum-tight enclosure configured to be maintained at the second pressure level different from the first pressure level. For example, the interior of the vacuum-tight enclosure may be maintained at the second pressure level, even when the vacuum chamber is maintained at the first pressure level which may be below the second pressure level.

In some embodiments, the light source and/or the light detector may be arranged in a vacuum-tight enclosure which may be arranged in the vacuum chamber. The vacuum-tight enclosure may be understood as a pressure-separated area inside the vacuum chamber which may be held at the second pressure level above the first pressure level. For example, the vacuum-tight enclosure may be an atmosphere box, i.e. an enclosure which may maintain atmospheric pressure therein, even when located in an evacuated vacuum chamber.

The size of the vacuum-tight enclosure may be adjusted to the size of the light source and/or the light detector which may be housed in the vacuum-tight enclosure.

The term “environment” as used herein may be understood as a volume or area which is pressure-separated from a main volume of the vacuum chamber in which the substrate is processed. A pressure-separated area, i.e. the “environment”, may maintain a second pressure level different from a first pressure level of an adjacent area, i.e. the main volume of the vacuum chamber in which the substrate is processed.

Typically, the first pressure level may be 1 mbar or less during operation, and the second pressure level may be 100 mbar or more, particularly atmospheric pressure. A component arranged in an environment under atmospheric pressure can be serviced more easily. For example, the cooling of a component arranged under atmospheric pressure may be reduced as compared to low-pressure conditions where hardly any heat convection exists. Further, a light source and/or a light detector may be used which is not necessarily configured to be operable under vacuum conditions. Higher-quality light sources and/or detectors can be used which may be less costly. Accordingly, a maintenance-friendly and/or a not necessarily vacuum-adapted light source and/or light detector can be used according to embodiments described herein.

In the embodiment exemplarily shown in FIG. 1, the light source 30 is arranged inside the vacuum chamber 11, e.g. inside a main volume of the vacuum chamber 11 in which the flexible substrate is processed, and the light detector 40 is arranged outside the vacuum chamber 11, i.e. in an atmospheric environment with a second pressure level (atmospheric pressure) different from the first pressure level in the main volume of the vacuum chamber. Alternatively, the light source may be arranged outside the vacuum chamber, or both the light source and the light detector may be arranged outside the vacuum chamber.

Arranging the light detector 40 in the environment 50 outside the vacuum chamber 11 has the advantage that servicing the light detector 40 is particularly easy. Further, the alignment of the light detector 40 and/or of the optical path of the light beam 31 is facilitated, and re-alignment is possible also after evacuation of the vacuum chamber 11. In particular, the optical path of the light beam 31 may be adjusted also during operation of the processing system, when the vacuum chamber 11 is evacuated. Evacuating the vacuum chamber 11 may slightly affect the positional relationship between individual components in the optical path, e.g. the substrate supports or the light source such that realignment of the light detector after evacuation of the vacuum chamber 11 may be beneficial.

In some embodiments, which may be combined with other embodiments described herein, the light source 30 may be arranged on a first side of the substrate transportation path, e.g. below the substrate transportation path in a vertical direction. The light beam 31 may be directed upward between a gap between the first substrate support 22 and the second substrate support 24. The light beam may propagate through an unsupported free-span portion of the flexible substrate between the first substrate support 22 and the second substrate support 24, and may be guided through a wall 12 of the vacuum chamber 11 toward the environment 50 outside the vacuum chamber. The light detector 40 may be arranged on the second side of the substrate transportation path, e.g. above the vacuum chamber, such as on top of the vacuum chamber 11.

In some embodiments, which may be combined with other embodiments described herein, a window 55 may be provided in the wall 12 of the vacuum chamber 11. The light beam 31 having propagated through the flexible substrate 10 may be guided to the environment 50 outside the vacuum chamber through the window 55, as is schematically depicted in FIG. 1.

In some embodiments, the transport system configured to transport the flexible substrate 10 along a substrate transportation path P may be a roller assembly including a plurality of guiding rollers configured to guide the flexible substrate on a respective roller surface. At least one roller may be an active roller with a drive or motor for rotating the roller. In some embodiments, more than one active rollers may be provided. For example, a storage spool, the coating drum and/or the wind-up spool may be active rollers. In some embodiments, the roller assembly may include one or more passive rollers.

An “active” roller or roll as used herein may be understood as a roller that is provided with a drive or a motor for actively moving or rotating the respective roller. For example, an active roller may be adjusted to provide a predetermined torque. Active rollers can be configured as substrate tensioning rollers configured for tensioning the substrate with a predetermined tensioning force during operation. A “passive” roller as used herein may be understood as a roller or roll that is not provided with a drive for actively moving or rotating the passive roller. The passive roller may be rotated by the frictional force of the flexible substrate that may be in direct contact with an outer roller surface during operation.

In the present disclosure, a “roll” or “roller” may be understood as a device which provides a surface with which the flexible substrate or part of the flexible substrate may come in contact during transport of the flexible substrate along the substrate transportation path in the deposition apparatus. At least a part of the roller as referred to herein may include a circular-like shape for contacting the flexible substrate 10 during transport. The substantially cylindrical shape may be formed about a straight longitudinal axis. According to some embodiments, a roller may be a guiding roller adapted to guide a substrate while the substrate is transported, e.g. during a deposition process or while the substrate is present in the deposition apparatus. The roller may be configured as a spreader roller, i.e. an active roller adapted for providing a defined tension for the flexible substrate, a processing roller, e.g. a coating drum, for supporting the flexible substrate while being coated, a deflecting roller for deflecting the substrate along the curved substrate transportation path, an adjusting roller, a storage spool, a wind-up spool etc.

The first substrate support 22 may be a first roller of the roller assembly, and the second substrate support 24 may be a second roller of the roller assembly. The first roller and the second roller may be adjacent rollers with a gap formed therebetween for conducting a transmission measurement on the free-span portion of the flexible substrate between the first roller and the second roller.

FIG. 2 shows a schematic view of a processing system according to some embodiments described herein. The setup of the vacuum chamber, the light source as well as the transport system may correspond to the respective features of the processing system 100 shown in FIG. 1, so that reference can be made to the above explanations which are not repeated here.

As is exemplarily depicted in FIG. 2, the light source 30 is arranged inside the vacuum chamber on a first side of the substrate transportation path, e.g. below the substrate transportation path in a vertical direction. The light detector is arranged on a second side of the substrate transportation path, e.g. above the substrate transportation path in the vertical direction. The light beam 31 can be directed from the light source 30 through an unsupported portion of the flexible substrate between the first substrate support 22 and the second substrate support 24. The light detector 40 is arranged in an environment 50 configured for a second pressure level different from the first pressure level in a main volume of the vacuum chamber 11.

Therein, a vacuum-tight enclosure 51 is provided in the vacuum chamber 11. The vacuum-tight enclosure may be an atmosphere box such that the environment 50 inside the vacuum-tight enclosure may be held at atmospheric pressure independently of the first pressure level in the main volume of the vacuum chamber where the flexible substrate is processed.

In some embodiments, which may be combined with other embodiments described herein, one or more enclosure windows 56 may be provided in a wall 52 of the vacuum-tight enclosure. Accordingly, the light beam 31 having propagated through the flexible substrate can propagate through the window into the vacuum-tight enclosure 51 and be detected by the light detector 40 for conducting a transmission measurement of the substrate. Accordingly, the light detector 40 may be no vacuum compatible light detector. Further, reduced cooling of the light detector may be sufficient.

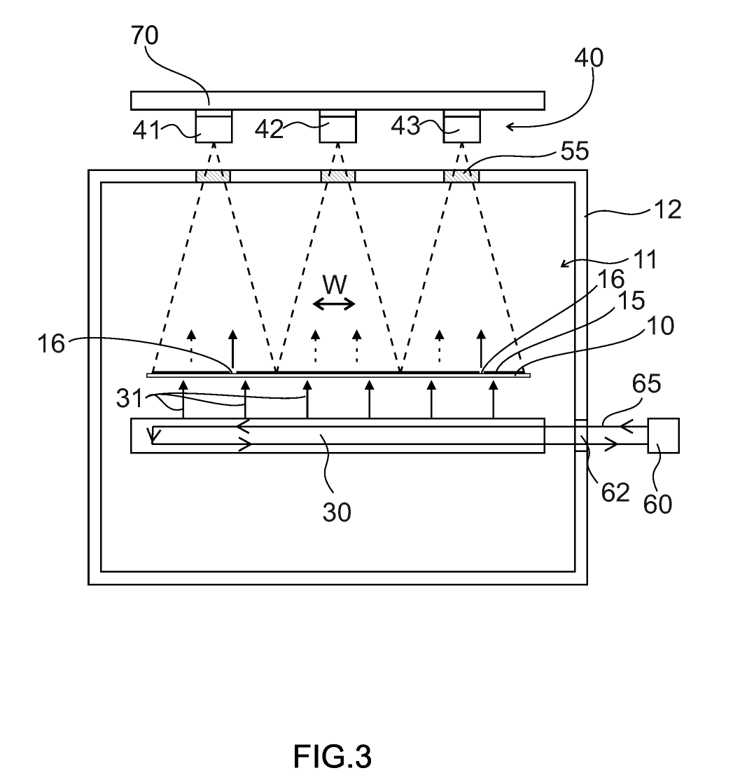

FIG. 3 shows a schematic sectional view of a processing system according to some embodiments described herein. Most of the features of the processing system of FIG. 3 may correspond to the respective features of the processing system shown in FIG. 1, so that reference can be made to the above explanations which are not repeated here.

As is depicted in the side view of FIG. 3, the light source 30 may be arranged inside the vacuum chamber 11, and the light detector 40 may be arranged outside the vacuum chamber, for example behind one or more windows 55 provided in the wall 12 of the vacuum chamber.

In some embodiments, the light detector 40 may include two or more detector units such as cameras. For example, in the embodiments shown in FIG. 3, the light detector 40 includes a first detector unit 41, e.g. a first camera, a second detector unit 42, e.g. a second camera, and a third detector unit 43, e.g. a third camera. Each detector unit may be configured to inspect a portion of the flexible substrate in a width direction W of the flexible substrate. The width direction W of the flexible substrate may be a direction parallel to a plane of the substrate and perpendicular to the length direction of the flexible substrate which is the direction of the substrate transportation path P.

In some embodiments, the flexible substrate may have a width of 100 mm or more, particularly 300 mm or more, or even 1 m or more. In order to inspect the flexible substrate over the entire width, it may be reasonable to arrange two, three or more detector units next to each other in the width direction W of the flexible substrate 10. For example, the first detector unit 41 may be provided for inspecting a first side portion of the flexible substrate, the second detector unit 42 may be provided for inspecting a center portion of the flexible substrate, and the third detector unit 43 may be provided for inspecting a second side portion of the flexible substrate.

A distance between the substrate transportation path P and the light detector 40 may be set as appropriate. For example, for detecting small defects (e.g. defects having diameters of 10 μm or less or 5 μm or less) in a coating layer deposited on the flexible substrate 10, it may be beneficial to arrange the light detector 40 close to the flexible substrate (i.e. close to the substrate transportation path), for example at a distance from 5 cm to 30 cm, particularly from 10 cm to 20 cm from the flexible substrate. In this case, the light detector 40 may be arranged in a vacuum-tight enclosure 51 arranged inside a main volume of the vacuum chamber, as explained above in more detail. In some embodiments, the light detector may be located at a larger distance from the substrate transportation path, e.g. at a distance from 10 cm to 200 cm, particularly from 50 cm to 120 cm. In this case, the light detector 40 may be arranged outside the vacuum chamber, e.g. behind one or more windows 55 in the wall 12 of the vacuum chamber, as is depicted in FIG. 3.

The distance between the light detector 40 and the substrate transportation path P may depend on further parameters such as the inspection width, the substrate width, the number of detector units, the focal length of the light detector etc. In some cases, the dimensions of the vacuum chamber 11 may not allow the assembly of the light detector within the vacuum chamber. Accordingly, as appropriate, the light detector may be arranged outside the vacuum chamber or in a vacuum-tight enclosure provided in a main volume of the vacuum chamber.

As is schematically depicted in FIG. 3, three detector units may be mounted on top of the vacuum chamber 11 to look through windows in the vacuum chamber 11 to conduct a transmission measurement of the flexible substrate.

In some embodiments, which may be combined with other embodiments described herein, the light source 30 may be configured for generating a light beam 31 having a width of 10 cm or more, particularly 20 cm or more, more particularly 30 cm or more, or even 50 cm or more. In some embodiments, a light beam with a width of 1 m or more may be generated by the light source. The width of the light beam 31 may be adapted to a width of the flexible substrate or to a width of a coating layer deposited on the flexible substrate that is to be inspected. For example, if the coating layer to be inspected has a width of 50 cm or more in the width direction W, the light source 30 may be configured to generate a light beam with essentially a corresponding width of 50 cm or more in the width direction W.

Therein, the width of the light beam 31 may be measured at a position where the light beam 31 crosses the substrate transportation path P. Accordingly, in some embodiments, a light beam with an initially smaller width may be generated, wherein the light beam may be expanded in the width direction of the flexible substrate, e.g. by respective optical devices (e.g. as expansion lenses), such that the light beam 31 has a larger width at a position where the light beam crosses the substrate transportation path.

In some embodiments, the light beam 31 may already be generated with a broad width. For example, the light source 30 may have an exit slit for the light beam which may have a slit width of 20 cm or more, 50 cm or more, or even 1 m or more. The slit may be shaped such that a light beam with a width as appropriate can be generated and directed toward the flexible substrate. A “thickness” of the slit (in the direction of the substrate transportation path) may be less than the slit width, e.g. 3 cm or less or 1 cm or less, such that a light beam with an extended width and a small thickness can be formed by the slit.

In some embodiments, which may be combined with other embodiments described herein, the light source 30 may be configured as a lighting strip having a width of 20 cm or more, 50 cm or more, or even 1 m or more. In some implementations, an LED light source, e.g. an LED light source configured as a lighting strip, may be provided. The LED lighting strip may be configured to generate a wide (e.g. 20 cm or more in the width direction W) light beam with a small thickness (e.g. 2 cm or less in the direction of the substrate transportation path P).

In some embodiments, the light source may be an LED light source, a laser light source, a lamp such as a halogen lamp, a light source providing light in a visible range (e.g. between 400 nm and 800 nm), a UV light source, or an IR light source.

In some embodiments, which may be combined with other embodiments described herein, a cooling device 60 may be provided for cooling at least one of the light source 30 and the light detector 40. For example, when the light source 30 is arranged inside the vacuum chamber, cooling of the light source 30 may be beneficial.

FIG. 3 shows a cooling device 60 including a cooling circuit 65 for a cooling medium, e.g. water, configured for cooling the light source 30 which is arranged inside the vacuum chamber 11. The cooling device 60 may include a water circuit.

A vacuum feed-through 62 may be provided in the wall 12 of the vacuum chamber 11 for supplying the cooling medium into the vacuum chamber 11 and out of the vacuum chamber 11. In some embodiments, a controller may be provided for adjusting the temperature of the light source as appropriate or for preventing an overheating of the light source.

In some embodiments, which may be combined with other embodiments described herein, one or more vacuum feed-throughs may be arranged in the wall 12 of the vacuum chamber 11 for supplying the light source 30 and/or the light detector 40 with at least one or more of a cooling medium, e.g. water, electricity, a control signal, a detector signal, and an operating voltage. For example, one or more vacuum feed-throughs may be provided for introducing one or more cooling tubes or hoses, one or more power cables and/or one or more control cables into the vacuum chamber and/or into the vacuum-tight enclosure arranged in the vacuum chamber. In some embodiments, also the vacuum-tight enclosure may have one or more vacuum feed-throughs for supplying a cooling medium and/or electricity from a main volume of the vacuum chamber into the inner volume of the vacuum-tight enclosure. The light detector and/or the light source may be cooled and/or powered by the media supplied into the vacuum chamber 11 via one or more vacuum feed-throughs.

In some embodiments, which may be combined with other embodiments described herein, the transport system may be configured to guide the flexible substrate at a speed of 1 m/s or more, particularly 5 m/s or more, more particularly 10 m/s or more, or even 15 m/s or more. A high speed R2R coating system may be provided. A reliable inspection of defects in the flexible substrate may be possible in spite of the high guiding speed of the flexible substrate. The guiding speed of the flexible substrate may be determined by an active roller, also referred to as the “master roller”, which may be preset to rotate at a predetermined rotation speed. One or more further active rollers may be tension-controlled rollers such that the tension of the substrate can be controlled as appropriate and an extensive or an insufficient substrate tension can be avoided.

In other embodiments, e.g. in sputter deposition apparatuses, the transport system may be configured for a lower guiding speed of the flexible substrate, e.g. a guiding speed of 10 m/min or less.

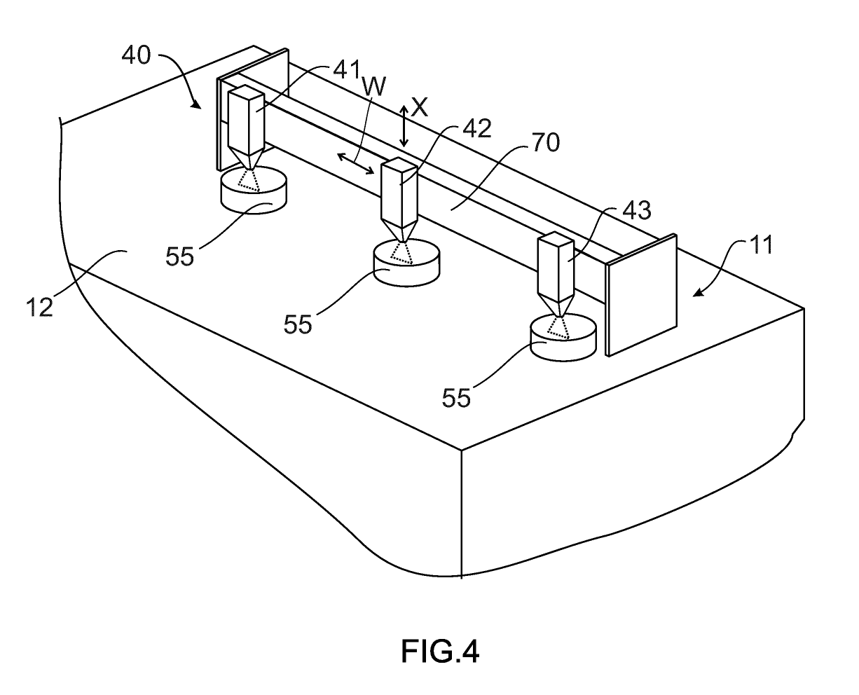

As is schematically depicted in FIG. 3, the detector units (e.g. the first detector unit 41, the second detector unit 42, and the third detector unit 43) may be arranged behind an associated window 55, respectively, wherein the windows may be arranged in a linear row extending in the width direction W of the flexible substrate. Each window may be associated to a part of the flexible substrate in the width direction W of the flexible substrate. The arrangement of the detector units behind a respective window is also shown in FIG. 4 in more detail.

FIG. 4 shows a perspective top view of a vacuum chamber 11 of a processing system according to embodiments described herein. In the embodiments of FIG. 4, the detector units of the light detector 40 are arranged outside the vacuum chamber 11 behind a respective window.

In some embodiments, the light detector 40 may be movably held on a detector support 70 such that the position of the light detector 40 with respect to the flexible substrate can be adjusted. For example, the light detector 40 may be movably mounted to the detector support 70 such that the light detector 40 can be moved with respect to the detector support in the direction X of the light beam 31, i.e. in a direction transverse or perpendicular to the surface of the flexible substrate. A focal length can be adjusted. In some embodiments, the light detector 40 may be movably mounted to the detector support 70 such that the light detector 40 can be moved in a direction perpendicular to the light beam 31, e.g. in the width direction W and/or in the direction Y of the substrate transportation path. The portion of the substrate to be inspected by the light detector can be adjusted. The detector support 70 can be configured as a support bar provided on top of the vacuum chamber in some embodiments.

Alternatively or additionally, in some embodiments, the light detector 40 and/or the light source 30 may be attached for a swivel movement around one or more swivel axes. For example, one or more detector units of the light detector 40 and/or the light source 30 can be pivoted around an axis such that the light beam 31 may have an angle with respect to the flexible substrate 10. In some embodiments, the light beam may impinge on the flexible substrate at an angle of incidence from 0° to 10°. In some implementations, an angle of incidence on the web of more than 0°, for example about 5°, may be beneficial. The angle of incidence on the web may be adjustable by pivoting both the light source 30 and the light detector 40.

FIG. 4 shows two or more detector units (e.g. the first detector unit 41, the second detector unit 42, and the third detector unit 43) which are movably held on the detector support 70 configured as a support bar which may be arranged on top of the vacuum chamber 11, respectively. The position of each of the two or more detector units can be adjusted as appropriate. For example, the support bar may extend essentially in the width direction W, and the detector units may be relocably fixed to the support bar. Accordingly, each detector unit can be shifted in the width direction W and/or in the direction X of the light beam 31 and fixed at an appropriate position. The detector units can be easily adjusted and serviced. Further, also the position of the support bar may be adjustable.

In some embodiments, which may be combined with other embodiments described herein, the processing system may include one or more deposition units configured for coating the flexible substrate with one or more layers. The inspection system may be arranged downstream from the one or more deposition units and configured for inspecting the one or more layers. Accordingly, defects in one or more coating layers deposited on the flexible substrate may be detected inline, i.e. inside the processing system during transport of the flexible substrate downstream from the deposition units.

The inspection system may be configured for detecting defects such as winding defects or coating defects, e.g. pinholes, cracks or other openings, in one or more layers deposited on the flexible substrate. For example, a freshly coated stack of layers may be continuously inspected by the inspection system. Therein, at least one of the light source and the light detector of the inspection system may be configured to be operated under vacuum conditions.

For example, defects, e.g. pinholes, cracks or openings in the deposited stack of layers, having a size of 50 μm or less, particularly 30 μm or less, more particularly 15 μm or less, or even 5 μm or less, may be detected with the inspection system. The size (e.g. the maximum diameter) of one or more detected defects and/or the number of defects per surface area may be determined.

Estimating the number and approximate size of defects in the coating layers deposited on the flexible substrate may be beneficial. Inspecting the coated substrate may be reasonable in order to check the coating result. In some embodiments, the number of defects in a stack of coating layers should be minimized. In some embodiments, a defect with a size (e.g. a maximum diameter) of 30 μm or more may impair the functionality of the deposited stack of layers. Accordingly, the defect inspection device may be configured for detecting defects with a size of 30 μm or more.

In some embodiments, the processing system may be configured for depositing a stack of layers on a first main surface of the flexible substrate, particularly wherein the outermost layer of the stack of layers may be a metal layer, e.g. a Cu-layer or an aluminum layer deposited on a transparent or semi-transparent flexible substrate. The layer quality of the outermost layer may be such that the outermost layer has essentially no defects or pinholes with a size of 30 μm or more, that the outermost layer has less than 10 defects or pinholes with a size from 15 μm to 30 μm per 625 cm² surface area (A4-sheet area), and/or that the outermost layer has less than 15 defects or pinholes with a size from 5 μm to 15 μm per 625 cm² surface area (A4-sheet area). The inspection system may be configured to inspect whether these or similar quality properties of the coated stack of layers are given.

FIG. 4 shows the flexible substrate 10 with one or more coating layers 15 deposited thereon. One or more defects 16 are exemplarily shown as openings or pinholes in the one or more coating layers 15. The transmission of the flexible substrate at the positions of the one or more defects 16 may be increased. Accordingly, particularly by providing a light detector with a spatial resolution, the number, size, and/or the position of the one or more defects 16 may be inspected. A reliable quality control of one or more coating layers 15 deposited on the substrate is provided.

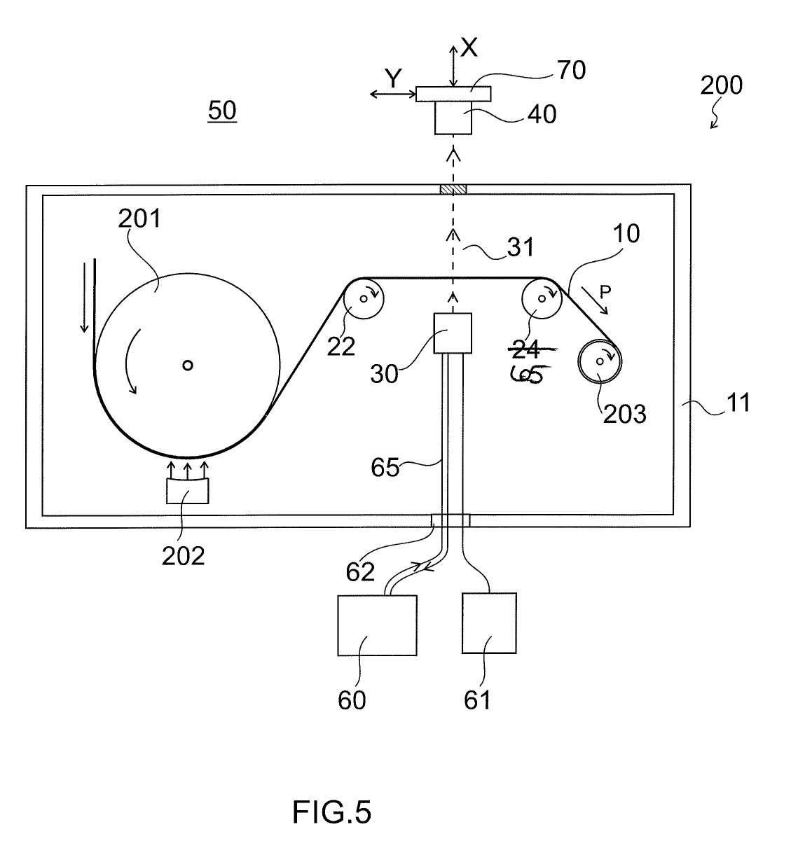

FIG. 5 shows a schematic side view of a deposition apparatus 200 for coating a flexible substrate 10 with one or more coating layers according to embodiments described herein. The deposition apparatus 200 includes a vacuum chamber 11, wherein the vacuum chamber 11 may include two or more vacuum compartments which may have a sealable passage arranged therebetween. For example, the vacuum chamber may include a deposition chamber for housing one or more deposition units configured for coating the flexible substrate, and a wind-up chamber configured for housing a wind-up spool for winding the flexible substrate thereon after deposition. A sealing device may be arranged in a wall between the deposition chamber and the wind-up chamber such that the wind-up chamber can be vented, while the deposition chamber may be maintained in an evacuated state. The exchange of the wind-up spool may be facilitated. In some embodiments, an inspection system is arranged in the wind-up chamber, e.g. directly upstream from the wind-up spool.

In the embodiment depicted in FIG. 5, the vacuum chamber 11 houses the coating drum 201 configured for guiding the flexible substrate 10 past one or more deposition units 202 and the wind-up spool 203 for winding the flexible substrate thereon after deposition. A roller assembly for guiding the flexible substrate 10 along the substrate transportation path P is provided, wherein the roller assembly includes a first roller and a second roller arranged at a distance from the first roller. The second roller may be arranged directly upstream from the wind-up spool 203.

An inspection system for inspecting the flexible substrate (namely, for inspecting one or more coating layers deposited on the flexible substrate) is provided. The inspection system includes a light source 30 configured to direct a light beam 31 through an unsupported portion of the flexible substrate 10 between the first roller and the second roller, and a light detector 40 for detecting the light beam 31 for conducting a transmission measurement of the flexible substrate. Therein, at least one of the light source 30 and the light detector 40 is arranged in an environment 50 configured for a second pressure level different from a first pressure level in the vacuum chamber 11.

A cooling device 60 for cooling the light source 30 may be provided, including a cooling circuit 65 for a cooling medium, e.g. water. Further, a power supply 61 for powering the light source 30 may be provided outside the vacuum chamber, wherein a power cable may connect the power supply 61 with the light source 30. The power cable and/or a supply line of the cooling device 60 for the cooling medium may be guided through a wall 12 of the vacuum chamber 11 via one or more vacuum feed-throughs 62.

The light detector 40 may be arranged outside the vacuum chamber. Further, the light detector 40 may be movably mounted on detector support such that the position of the light detector 40 may be adjusted in the direction X of the light beam 31, in the width direction W of the flexible substrate and/or in the direction Y of the substrate transportation path.

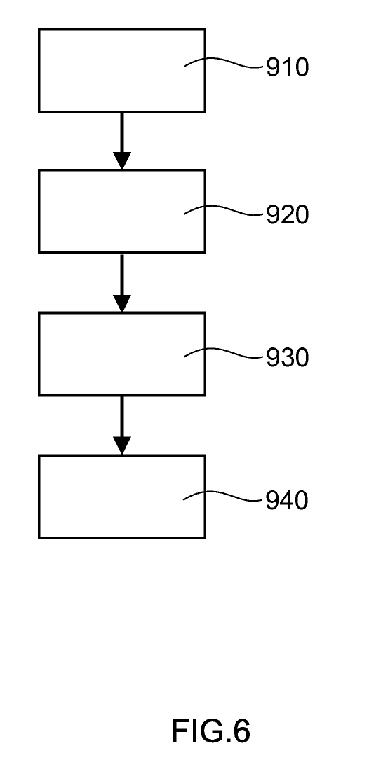

According to a further aspect described herein, a method of processing a flexible substrate 10 is provided. FIG. 6 is a flow diagram of a processing method according to embodiments described herein.

In box 910, the flexible substrate 10 is guided through a vacuum chamber 11 along a substrate transportation path, wherein the vacuum chamber 11 is evacuated to a first pressure level and wherein the flexible substrate 10 is supported by a first substrate support 22 and by a second substrate support 24 arranged at a distance from the first substrate support 22. In optional box 920, the flexible substrate is guided past one or more deposition units provided in the vacuum chamber such that one or more layers are deposited on the flexible substrate. In box 930, a light beam 31 is directed through an unsupported portion of the flexible substrate 10 between the first substrate support 22 and the second substrate support 24. In box 940, the light beam 31 having passed through the flexible substrate 10 is detected for conducting a transmission measurement of the flexible substrate, and particularly for conducting a transmission measurement for detecting one or more defects in the one or more coating layers deposited on the flexible substrate. Defects in the one or more coating layers may be detected and/or inspected. Therein, at least a portion of the light beam propagates through an environment 50 with a second pressure level different from the first pressure level.

The first pressure level may be provided in a main volume of the vacuum chamber, where the flexible substrate is processed, e.g. transported and coated. Therein, the first pressure level may be below 10 mbar or below 1 mbar during deposition.

The second pressure level in the environment 50 may be above 100 mbar, particularly atmospheric pressure.

In some embodiments, the light source and/or the light detector are arranged outside the vacuum chamber, e.g. behind one or more windows 55 in a wall 12 of the vacuum chamber. In some embodiments, the light source and/or the light detector are arranged in a vacuum-tight enclosure arranged in the vacuum chamber.

In particular, according to some embodiments described herein, the light beam 31 may be generated in the vacuum chamber at the first pressure level, and/or the light beam 31 may be detected outside the vacuum chamber 11 or inside a vacuum-tight enclosure 51 arranged in the vacuum chamber 11 and held at the second pressure level.

According to some embodiments described herein, detecting the light beam 31 may comprise detecting a transmittivity of the unsupported portion of the flexible substrate 10 for detecting defects of the flexible substrate. Particularly, at least one of winding defects, pinholes, openings, and cracks, in one or more layers deposited on the flexible substrate may be detected. An improved quality control is possible, as the defects are inspected inline, i.e. in the vacuum chamber during the deposition process or immediately subsequent to the deposition process, before the coated substrate is rewound onto a wind-up spool.

According to embodiments described herein, a precise inline defect inspection in a R2R deposition apparatus is possible, particularly at a transport speed of the flexible substrate up to 15 m/s or more.

While the foregoing is directed to embodiments of the disclosure, other and further embodiments of the disclosure may be devised without departing from the basic scope thereof, and the scope thereof is determined by the claims that follow.

1. A processing system for processing a flexible substrate, comprising:
a vacuum chamber;
a transport system configured to guide a flexible substrate through the vacuum chamber along a substrate transportation path, wherein the transport system comprises a first substrate support and a second substrate support arranged at a distance from the first substrate support; and
an inspection system for inspecting the flexible substrate, comprising:
a light source arranged inside the vacuum chamber and configured to direct a light beam through a portion of the flexible substrate between the first substrate support and the second substrate support, wherein a cooling device is provided for cooling the light source; and
a light detector for detecting the light beam for conducting a transmission measurement of the flexible substrate,
wherein the light detector is arranged in an environment configured for a second pressure level different from a first pressure level in the vacuum chamber.

2. The processing system of claim 1, wherein the light detector is arranged outside the vacuum chamber.

3. The processing system of claim 1, wherein the transport system is a roller assembly, the first substrate support is a first roller, and the second substrate support is a second roller.

4. The processing system of claim 1, wherein the light source is arranged on a first side of the substrate transportation path and the light detector is arranged on a second side of the substrate transportation path opposite the first side.

5. The processing system of claim 1, wherein the light detector is arranged outside the vacuum chamber behind one or more windows provided in a wall of the vacuum chamber.

6. The processing system of claim 1, wherein the cooling device comprises a cooling circuit for a cooling medium.

7. The processing system of claim 1, wherein the light source is configured for generating a light beam having a width of 20 cm or more.

8. The processing system of claim 1, wherein the light detector comprises two, three or more detector units arranged next to each other in a width direction of the flexible substrate.

9. The processing system of claim 1, wherein the light detector is movably held on a detector support.

10. The processing system of claim 1, further comprising one or more deposition units configured for coating the flexible substrate with one or more layers, wherein the inspection system is arranged downstream from the one or more deposition units and configured for inspecting the one or more layers.

11. The processing system of claim 1, wherein the transport system is configured to guide the flexible substrate at a speed of 1 m/s or more.

12. A deposition apparatus for coating a flexible substrate with one or more layers, comprising:
a vacuum chamber comprising a coating drum configured for guiding the flexible substrate past one or more deposition units and a wind-up spool for winding the flexible substrate thereon;
a roller assembly configured to guide the flexible substrate along a substrate transportation path from the coating drum to the wind-up spool, wherein the roller assembly comprises a first roller and a second roller arranged at a distance from the first roller; and
an inspection system for inspecting the flexible substrate, comprising:
a light source arranged inside the vacuum chamber and configured to direct a light beam through a portion of the flexible substrate between the first roller and the second roller, wherein a cooling device is provided for cooling the light source; and
a light detector for detecting the light beam for conducting a transmission measurement of the flexible substrate,
wherein at least one of the light source and the light detector is arranged in an environment configured for a second pressure level different from a first pressure level in the vacuum chamber.

13. A method of processing a flexible substrate, comprising:
guiding the flexible substrate through a vacuum chamber along a substrate transportation path, wherein the vacuum chamber is evacuated to a first pressure level and wherein the flexible substrate is supported by a first substrate support and by a second substrate support arranged at a distance from the first substrate support;
directing a light beam from a light source arranged inside the vacuum chamber through a portion of the flexible substrate between the first substrate support and the second substrate support wherein a cooling device is provided for cooling the light source; and
detecting the light beam having passed through the flexible substrate for conducting a transmission measurement of the flexible substrate, wherein at least a portion of the light beam propagates through an environment with a second pressure level different from the first pressure level.

14. The method of claim 13, wherein the light beam is generated inside the vacuum chamber, and wherein the light beam is detected outside the vacuum chamber or inside a vacuum-tight enclosure arranged in the vacuum chamber.

15. The method of claim 13, wherein detecting the light beam comprises detecting a transmittivity of said portion of the flexible substrate for detecting defects of the flexible substrate.

16. The processing system of claim 1, wherein the light detector is arranged in a vacuum-tight enclosure, arranged inside the vacuum chamber.

17. The processing system of claim 1, wherein the light detector is arranged in an atmosphere box arranged inside the vacuum chamber.

18. The processing system of claim 1, wherein the light source is configured for generating a light beam having a width of 50 cm or more.

19. The processing system of claim 1, wherein the light source comprises a lighting strip having a width of 20 cm or more.

20. The processing system of claim 8, wherein the two, three or more detector units are arranged behind one or more windows in a wall of the vacuum chamber or behind one or more enclosure windows in a wall of a vacuum-tight enclosure.
